(19) United States
(12) Patent Application Publication
(10) Pub. No.: US 2024/0227112 A1
(43) Pub. Date: Jul. 11, 2024

(54) EQUIPMENT, APPARATUS AND METHOD OF CHEMICAL MECHANICAL POLISHING (CMP)

(71) Applicant: Samsung Electronics Co., Ltd., Suwon-si (KR)

(72) Inventors: SEUNGJUN LEE, Suwon-si (KR); Jinoh Im, Suwon-si (KR); ILYOUNG YOON, Suwon-si (KR)

(21) Appl. No.: 18/225,909

(22) Filed: Jul. 25, 2023

(30) Foreign Application Priority Data
Jan. 11, 2023 (KR) 10-2023-0004216

(51) Int. Cl. B24B 37/013

(52) U.S. Cl. CPC B24B 37/013

(57) ABSTRACT

A chemical mechanical polishing apparatus according to an example embodiment includes a polishing platen; a polishing pad which is located on the polishing platen and includes a polishing surface; a slurry supplier configured to supply a slurry to the polishing pad; a polishing head which is located above the polishing pad and configured to mount a wafer thereon; and an additional CMP process condition generator which generates an additional chemical mechanical polishing (CMP) process condition according to a type of residue when there is a residue on a wafer after a CMP process is performed on the wafer.

### CROSS-REFERENCE TO RELATED APPLICATION

This application claims priority under 35 U.S.C. § 119 to and the benefit of Korean Patent Application No. 10-2023-0004216 filed in the Korean Intellectual Property Office on Jan. 11, 2023, the entire contents of which are incorporated herein by reference.

### BACKGROUND

### (1) Field

The present disclosure relates to equipment, an apparatus, and a method of chemical mechanical polishing (CMP) and more particularly, a chemical mechanical polishing equipment, apparatus, and method which are capable of performing customized additional CMP according to residues of the wafer.

### (2) Description of the Related Art

A chemical mechanical polishing (hereinafter, abbreviated as ‘CMP’) apparatus is used for a polishing process to planarize a surface of a semiconductor wafer. Generally, a semiconductor device is manufactured by selectively or repeatedly performing a process such as photolithography, etching, diffusion, chemical vapor deposition (CVD), ion implantation, or metal deposition on the wafer. During this process, a chemical mechanical polishing (CMP) process using a chemical mechanical polishing (CMP) apparatus may be used to planarize a wafer.

During the CMP process, a slurry is supplied to be uniformly distributed on a surface of a polishing pad which rotates at a high speed and a surface of a semiconductor wafer which is required to be planarized is placed to be close to the polishing pad surface to process a target surface of the semiconductor wafer by a chemical action by the slurry and a physical action by a high speed rotate.

During the CMP process, if a CMP removed amount after polishing is insufficient, residues locally remain on the wafer in some cases. In this case, a rework called additional CMP is performed. However, in the related art, an engineer in charge checked the image of the wafer one by one based on the experience to check the presence of the residues and the thickness and then determined a process condition (recipe) required for the additional CMP.

Accordingly, the engineer manually checks the image of the wafer one by one and it takes a lot of time to determine the additional CMP condition according to the corresponding residue so that there is a problem in that the productivity is deteriorated.

Further, even when the additional CMP is requested for a plurality of wafers and states of the residues are different from each other, a process condition required for the additional CMP is set based on a specific residue state of a wafer (for example, having the most residues) to perform the additional CMP according to the same process condition. Accordingly, insufficient or excessive additional CMP is performed, which affects the distribution of the polishing film after CMP.

Further, it is difficult to determine an accurate required amount of additional CMP only with the residue image, so that there is a problem in that it is difficult to perform an accurate polishing.

### SUMMARY

The present disclosure is to provide a chemical mechanical polishing apparatus which efficiently polishes a wafer.

A chemical mechanical polishing apparatus according to an example embodiment includes a polishing platen; a polishing pad which is located on the polishing platen and includes a polishing surface; a slurry supplier configured to supply a slurry to the polishing pad; a polishing head which is located above the polishing pad and configured to mount a wafer thereon; and an additional CMP process condition generator which generates an additional chemical mechanical polishing (CMP) process condition according to a type of residue when there is a residue on a wafer after a CMP process is performed on the wafer.

An example embodiment, the additional CMP process condition generator includes a wafer image acquiring unit configured to acquire a wafer macro image captured by a camera after the CMP process is performed on the wafer; an image converter which converts the wafer macro image acquired by the wafer image acquiring unit into digital data to deduce an intensity value for each of a plurality of partitions of the wafer macro image; a residue type determining unit which determines a type of residue based on the digital data converted by the image converter; and an additional CMP process condition output unit which determines a wafer which requires an additional CMP process based on the type of residue determined by the residue type determining unit and outputs the additional CMP process condition corresponding to the determined wafer.

The type of residue is determined based on a region of the residue and a thickness of the residue.

The additional CMP process condition output unit further includes an intensity-thickness matching table in which the intensity value deduced by the image converter and the thickness of the residue match and are stored.

In another example embodiment, the additional CMP process condition generator includes a wafer image acquiring unit which acquires a wafer macro image captured by a camera after the CMP process is performed on the wafer; and a machine learning unit which constructs a machine learning model by performing the machine learning based on the wafer macro image acquired by the wafer image acquiring unit, digitally converted data from the wafer macro image, and an optimal additional CMP process condition corresponding to each macro image.

The machine learning unit applies the macro image of the wafer after the CMP process to the constructed machine learning model to determine a wafer which requires the additional CMP process and generate the additional CMP process condition corresponding to the determined wafer.

The machine learning unit includes a learning data acquiring unit which acquires a wafer macro image captured by the camera after the CMP process is performed, a residue type extracted from the digitally converted data from the wafer macro image, and an additional CMP process condition of the wafer based on the residue type; and a model training unit which inputs the wafer macro image and the residue type to the machine learning model to predict an additional CMP process condition corresponding to the residue type.

The residue type is labeling information which is acquired from a memory or directly input by a user based on a region of the residue extracted from the digitally converted data and thickness data of the residue.

The machine learning unit further includes: a learning data pre-processor which preprocesses the acquired data to allow the learning data acquiring unit to use the acquired data for the machine learning; and a learning data selecting unit which selects data required for learning, among the preprocessed data, according to a predetermined reference to determine which region of the wafer macro image corresponds to information of interest.

The model training unit inputs the wafer macro image and the residue type to a machine learning model to predict an additional CMP process condition corresponding to the residue type and receives a feedback of a result of the additional CMP process performed according to the predicted additional CMP process condition to update a parameter of the machine learning model.

Chemical mechanical polishing equipment according to an example embodiment includes: a chemical mechanical polishing apparatus which includes at least one chemical mechanical polishing unit which individually performs a chemical mechanical polishing (CMP) process on a wafer; an index unit which provides a space in which a cassette which accommodates a plurality of wafers is placed; a transport robot which transports the wafer between the chemical mechanical polishing apparatus and the index unit; a cleaning apparatus configured to remove a contaminated material remaining on a wafer after the CMP process is performed on the wafer; and an operation controller which generates a control signal according to an additional CMP process condition according to a type of residue when there is a residue on a wafer after the CMP process is performed on the wafer to transmit the control signal to the chemical mechanical polishing apparatus.

The chemical mechanical polishing unit includes a polishing platen; a polishing pad which is located on the polishing platen and includes a polishing surface; a slurry supplier which supplies a slurry to the polishing pad; a polishing head which is located above the polishing pad and configured to mount a wafer thereon; and an additional CMP process condition generator which generates an additional chemical mechanical polishing (CMP) process condition according to a type of residue to output the additional CMP process condition to the operation controller when there is a residue on a wafer after the CMP process is performed on the wafer.

The operation controller transmits a control signal corresponding to individual CMP process conditions to the chemical mechanical polishing unit.

In the example embodiment, the additional CMP process condition generator includes a wafer image acquiring unit which acquires a wafer macro image captured by a camera after the CMP process is performed on the wafer; an image converter which converts the wafer macro image into digital data to deduce an intensity value for each of a plurality of partitions of the wafer macro image; a residue type determining unit which determines a type of residue based on the digital data converted by the image converter; and an addition CMP process condition output unit which determines a wafer which requires an additional CMP process based on the type of residue determined by the residue type determining unit and outputs the additional CMP process condition corresponding to the determined wafer.

In another example embodiment, the additional CMP process condition generator includes a wafer image acquiring unit which acquires a wafer macro image captured by a camera after the CMP process is performed on the wafer; and a machine learning unit which constructs a machine learning model by performing the machine learning based on the wafer macro image acquired by the wafer image acquiring unit, digitally converted data from the wafer macro image, and an optimal additional CMP process condition corresponding to each macro image.

The machine learning unit includes a learning data acquiring unit which acquires a wafer macro image captured by the camera after the CMP process is performed on the wafer, a residue type extracted from the digitally converted data from the wafer macro image, and an additional CMP process condition of the wafer based on the residue type; and a model training unit which inputs the wafer macro image and the residue type to the machine learning model to predict an additional CMP process condition corresponding to the residue type.

The model training unit inputs the wafer macro image and the residue type to a machine learning model to predict an additional CMP process condition corresponding to the residue type and receives a feedback of a result of the additional CMP process performed according to the predicted additional CMP process condition to update a parameter of the machine learning model.

A chemical mechanical polishing method according to an example embodiment is a chemical mechanical polishing method performed by a chemical mechanical polishing apparatus including at least one chemical mechanical polishing unit which individually performs a chemical mechanical polishing (CMP) process on a wafer, and the method includes: acquiring a wafer macro image after the CMP process is performed on the wafer; determining an additional CMP process condition corresponding to a wafer which requires an additional CMP process, based on a type of a residue determined from the wafer macro image; transmitting a control signal corresponding to the determined additional CMP process condition to the chemical mechanical polishing unit; and performing the additional CMP process on the wafer by the chemical mechanical polishing unit based on the transmitted control signal.

The determining of an additional CMP process condition includes constructing a machine learning model by performing the machine learning based on the wafer macro image after the CMP process, digitally converted data from the wafer macro image, and an optimal additional CMP process condition corresponding to each macro image; and predicting a customized additional CMP process condition with respect to a wafer which requires the additional CMP process by applying the macro image of the wafer to the constructed machine learning model.

The determining of an additional CMP process condition further includes the updating a parameter of the machine learning model by receiving a feedback of a result of the additional CMP process performed according to the predicted additional CMP process condition.

According to example embodiments, a wafer from which a residues is generated is automatically determined to perform the additional CMP.

Further, even when the states of the residues of the wafers which require the additional CMP are different, a customized additional CMP for every wafer is performed to minimize the over-CMP.

### BRIEF DESCRIPTION OF THE DRAWINGS

FIG. 1 is a schematic plan view for explaining polishing equipment including a chemical mechanical polishing apparatus according to an example embodiment.

FIG. 2 is a schematic perspective view for explaining a chemical mechanical polishing unit according to an example embodiment.

FIG. 3 is a block diagram illustrating an additional CMP process condition generator according to an example embodiment.

FIG. 4 is a view illustrating an example of converting a macro image of a wafer into digital data.

FIG. 5 is a flowchart illustrating a method for performing an additional CMP process according to an example embodiment.

FIG. 6 is a table illustrating a residue type and an example of customized CMP process condition according to an example embodiment.

FIG. 7 is a flowchart illustrating a customized additional CMP process according to an example embodiment.

FIG. 8 is a block diagram illustrating an additional CMP process condition generator according to another example embodiment.

FIG. 9 is a block diagram illustrating a machine learning unit according to an example embodiment.

FIG. 10 is an example view illustrating a neural network model according to an example embodiment.

FIG. 11 is a flowchart illustrating a method for performing an additional CMP process according to another example embodiment.

FIG. 12 is a block diagram illustrating an example of a computer device according to an example embodiment.

### DETAILED DESCRIPTION OF THE EMBODIMENTS

In the following detailed description, only certain example embodiments of the present invention have been shown and described, simply by way of illustration. The present invention can be variously implemented and is not limited to the following example embodiments.

The drawings and descriptions are to be regarded as illustrative in nature and not restrictive. Like reference numerals designate like elements throughout the specification.

In addition, the size and thickness of each configuration shown in the drawings are arbitrarily shown for understanding and ease of description, but the present invention is not limited thereto. In the drawings, the thickness of layers, films, panels, regions, etc., are exaggerated for clarity. In the drawings, for understanding and ease of description, thicknesses of some layers and regions are exaggerated.

Further, it will be understood that when an element such as a layer, film, region, or substrate is referred to as being “on” another element, it can be directly on the other element or intervening elements may also be present. In contrast, when an element is referred to as being “directly on” another element, there are no intervening elements present. Further, when an element is “on” a reference portion, the element is located above or below the reference portion, and it does not necessarily mean that the element is located “above” or “on” in a direction opposite to gravity.

In addition, unless explicitly described to the contrary, the word “comprise”, and variations such as “comprises” or “comprising”, will be understood to imply the inclusion of stated elements but not the exclusion of any other elements.

Further, in the entire specification, when it is referred to as “on a plane”, it means when a target part is viewed from above, and when it is referred to as “on a cross-section”, it means when the cross-section obtained by cutting a target part vertically is viewed from the side.

In addition, the terms “-er”, “-or” and “module” described in the specification mean units for processing at least one function and operation and can be implemented by hardware components, software components, or a combination thereof.

In the present specification, “transmit” or “provide” includes not only directly transmit or provide, but also indirectly transmit or provide by means of the other device or using an indirect route.

In the present specification, expression described in a singular form may be interpreted in the singular or plural unless an explicit expression such as “one” or “single” is not used.

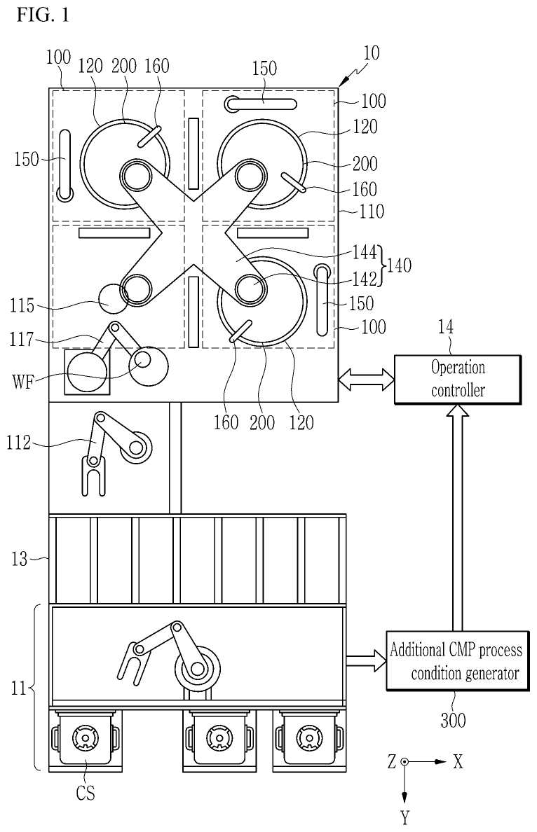

Hereinafter, a chemical mechanical polishing apparatus according to an example embodiment will be described with reference to FIGS. 1 to 3.

FIG. 1 is a schematic plan view for explaining polishing equipment including a chemical mechanical polishing apparatus according to an example embodiment.

Referring to FIG. 1, polishing equipment according to an example embodiment includes a chemical mechanical polishing apparatus 10, an index unit 11, a transport robot 112, a cleaning apparatus 13, and an operation controller 14.

The chemical mechanical polishing apparatus 10 polishes a wafer WF. The chemical mechanical polishing apparatus 10 according to the example embodiment includes a lower base 110, a load cup 115, a polishing platen 120, a polishing pad 200, a carrier head assembly 140, a pad conditioner 150, a slurry supplier 160, and an additional CMP process condition generator 300. According to the example embodiment, the chemical mechanical polishing apparatus 10 includes a plurality of chemical mechanical polishing units 100, but is not limited thereto and may include only one chemical mechanical polishing unit 100. Each chemical mechanical polishing unit 100 is a device which individually performs the chemical mechanical polishing process on a wafer.

The plurality of chemical mechanical polishing units 100 may perform different chemical mechanical polishing processes on individual wafers under the individual CMP process conditions or perform the same chemical mechanical polishing process on the wafers under the same CMP process condition, in accordance with the control of the operation controller 14.

The wafer according to the example embodiment may be a substrate which is formed of or include a semiconductor or a non-semiconductor material. The wafer may include one or more layers formed on the substrate. For example, the layer includes a photoresist, a dielectric material, or a conductive material, but is not limited thereto. Further, the wafer may include a plurality of dies having a lattice structure with repeated patterns.

The index unit 11 may provide a space in which a cassette CS is placed. Wafers WF are accommodated in the cassette CS. The index unit 11 unloads the wafers WF from the cassette CS to transfer the wafers WF to the transport robot 112 or loads a wafer WF on which the polishing process is completed into the cassette CS. Further, the index unit 11 may unload only the wafers which require the additional CMP process from the cassette CS to transmit the wafers to the transport robot 112. In the index unit 11, a camera (not illustrated) to capture a surface of the wafer WF in which the polishing process is completed may be disposed.

The transport robot 112 may be disposed between the chemical mechanical polishing apparatus 10 and the index unit 11. The transport robot 112 transports the wafer WF between the chemical mechanical polishing apparatus 10 and the index unit 11. For example, the load cup 115 which is adjacent to the transport robot 112 may be disposed in the chemical mechanical polishing apparatus 10. The load cup 115 may provide a temporary waiting space for the wafer WF. Further, an exchanger 117 may be disposed between the transport robot 112 and the load cup 115. The exchanger 117 transports the wafer WF which is transported from the index unit 11 by the transport robot 112 to the load cup 115 or transports the wafer WF disposed on the load cup 115 to the transport robot 112.

The cleaning apparatus 13 may be disposed between the index unit 11 and the transport robot 112. The wafer WF which is polished by the chemical mechanical polishing apparatus 10 may be disposed on the load cup 115. The wafer WF disposed on the load cup 115 may be transported to the cleaning apparatus 13 by the transport robot 112 disposed to be adjacent to the load cup 115. The cleaning apparatus 13 cleans/removes contaminated material (e.g., slurry, particles, powder, etc.) remaining on the polished wafer WF. For example, the cleaning apparatus 13 cleans the wafer WF after the CMP process is performed on the wafer WF. The cleaned wafer WF is returned to the index unit 11 to be accommodated in the cassette CS. By doing this, the polishing process on the wafer WF is completed.

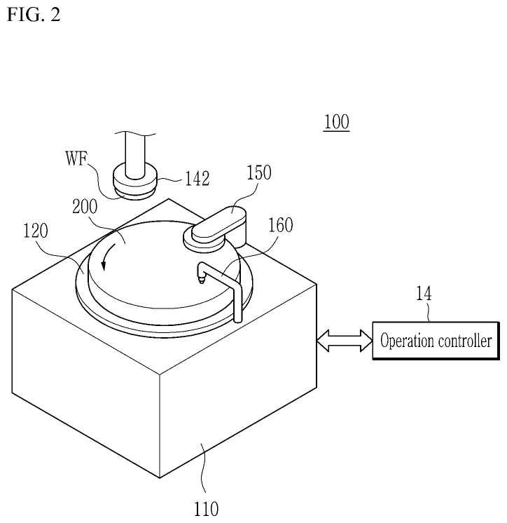

FIG. 2 is a schematic perspective view for explaining a chemical mechanical polishing unit 100 according to an example embodiment.

The chemical mechanical polishing unit 100 includes a polishing platen 120, a polishing pad 200, a polishing head 142, a pad conditioner 150, and a slurry supplier 160.

Referring to FIGS. 1 and 2, the lower base 110 may provide a lower structure of a chemical mechanical polishing apparatus according to an example embodiment. For example, the lower base 110 supports the load cup 115, the polishing platen 120, the polishing pad 200, the carrier head assembly 140, the pad conditioner 150, and the slurry supplier 160.

The polishing platen 120 may be disposed on an upper/top surface of the lower base 110. The polishing platen 120 is rotatable. For example, the polishing platen 120 rotates with a torque supplied from a motor (not illustrated) disposed in the lower base 110. The polishing platen 120 rotates around a first axis perpendicular to an upper/top surface of the polishing platen 120.

The polishing pad 200 is disposed on an upper/top surface of the polishing platen 120. The polishing pad 200 is rotatably supported by the polishing platen 120. The polishing pad 200 has a predetermined thickness in a third direction (Z-axis direction) perpendicular to a first direction (X-axis direction) and a second direction (Y-axis direction). The first and second directions may be horizontal directions perpendicular to each other and parallel to the upper/top surface of the polishing pad 200 and the upper/top surface of the lower base 110. The polishing pad 200 may be provided as a circular plate, but is not limited thereto.

The polishing pad 200 includes a polishing surface with a predetermined roughness. During the chemical mechanical polishing process, the polishing surface of the polishing pad 200 is in contact with the wafer WF to mechanically polish the wafer WF. In the example embodiment, the polishing surface may be an upper/top surface of the polishing pad 200.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element, there are no intervening elements present at the point of contact.

The polishing pad 200 may include a porous material such that the polishing pad 200 may have a plurality of micro spaces/recesses on the top surface and/or inside of the polishing pad 200. The micro spaces/recesses on the top surface of the polishing pad 200 may accommodate slurries provided during the chemical mechanical polishing process.

The carrier head assembly 140 is disposed on the lower base 110. The carrier head assembly 140 includes a polishing head 142 and an upper base 144.

The polishing head 142 provides the wafer WF onto the polishing pad 200. For example, the polishing head 142 provides the wafer WF such that a surface of the wafer WF to be polished is directed toward the polishing surface (e.g., upper/top surface) of the polishing pad 200. For example, the polishing head 142 accommodates the wafer WF in a vacuum suction manner, but is not limited thereto.

During the chemical mechanical polishing process, the polishing head 142 moves in the third direction (Z axis direction) to pressurize the wafer WF onto the polishing pad 200. For example, the polishing head 142 operates in the third direction (Z axis direction) using a pneumatic or hydraulic pressure cylinder to pressurize the wafer WF. During the chemical mechanical polishing process, the polishing head 142 rotates. For example, the polishing head 142 rotates with a torque transmitted from a motor (not illustrated). For example, the polishing head 142 rotates around a rotation axis which is perpendicular to the upper/top surface of the polishing pad 200. Accordingly, the wafer WF may be polished by the polishing pad 200.

The polishing head 142 may be disposed on the polishing platen 120 by the upper base 144. For example, as illustrated in FIG. 1, the upper base 144 has a shape in which two sticks/bars intersect (for example, a cross (or X) shape). The polishing head 142 is disposed on at least one end of the sticks/bars (cross) of the upper base 144. As the upper base 144 rotates, the polishing head 142 sequentially moves from the load cup 115 to each polishing platen 120. For example, the polishing head 142 moves to the polishing platen 120 after loading the wafer WF on the load cup 115 to polish the wafer WF. Further, the polishing head 142 unloads the polished wafer WF from the load cup 115.

The pad conditioner 150 may be disposed to be adjacent to the polishing pad 200. The pad conditioner 150 may perform the conditioning process on the polishing pad 200. By doing this, the pad conditioner 150 may stably maintain a state of the polishing surface of the polishing pad 200 to effectively polish the wafer WF during the chemical mechanical polishing process.

The slurry supplier 160 is disposed to be adjacent to the polishing pad 200. During the chemical mechanical polishing process, the slurry supplier 160 supplies the slurry onto the polishing pad 200.

The slurry supplier 160 includes a nozzle and a pipe which transports the slurry. The nozzle is disposed to be adjacent to (e.g., vertically overlap) the polishing pad 200. Accordingly, the slurry may be supplied onto the polishing pad 200 through the pipe and the nozzle.

The slurry supplied from the slurry supplier 160 includes a reactant (for example, deionized water for oxidization polishing), wear particle (for example, silicon dioxide for oxidization polishing) and a chemical reaction catalyst (for example, potassium hydroxide for oxidization polishing), but is not limited thereto.

The additional CMP process condition generator 300 generates an additional CMP process condition (a slurry amount, a pressure, a polishing time, and a rotation speed) according to a type of residue, for a wafer which requires an additional CMP due to the residues remaining on the wafer after the CMP process.

The operation controller 14 controls an operation of the polishing equipment depending on the CMP process condition to perform the chemical mechanical polishing process on each wafer. For example, the operation controller 14 transmits a control signal to at least one of the chemical mechanical polishing apparatus 10, the index unit 11, the transport robot 112, and the cleaning apparatus 13 to allow the apparatus to perform the chemical mechanical polishing process according to the transmitted control signal. At this time, the operation controller 14 transmits the control signal to only some of chemical mechanical polishing units 100 selected from the plurality of chemical mechanical polishing units 100. Further, the operation controller 14 individually transmits control signals corresponding to individual CMP process conditions to the plurality of chemical mechanical polishing units 100 or simultaneously transmits a control signal corresponding to the same CMP process condition.

Further, the operation controller 14 controls the operation of the polishing equipment in accordance with the additional CMP process condition generated in the additional CMP process condition generator 300 to perform the chemical mechanical polishing process on each wafer to be customized for the wafers which require the additional CMP process.

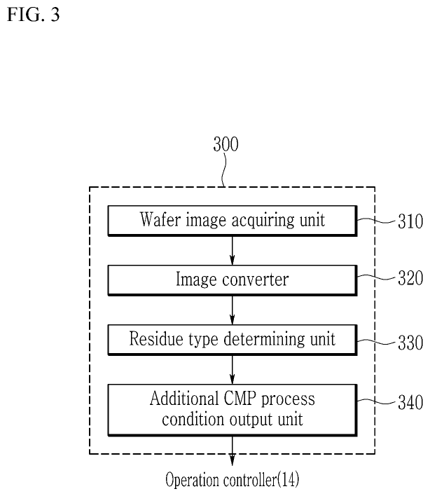

FIG. 3 is a block diagram illustrating an additional CMP process condition generator 300 according to an example embodiment.

The additional CMP process condition generator 300 according to an example embodiment includes a wafer image acquiring unit 310, an image converter 320, a residue type determining unit 330, and an additional CMP process condition output unit 340.

The wafer image acquiring unit 310 acquires an entire wafer image (hereinafter, referred to as “macro image”) after the CMP which is captured by the camera (not illustrated) provided in the index unit 11. In an example embodiment, the camera which captures a surface of the wafer after the CMP is provided in the index unit 11, but is not limited thereto, and may be provided in the cleaning apparatus 13.

The image converter 320 converts a macro image of the wafer acquired by the wafer image acquiring unit 310 into digital data to partition the digital data into a plurality of sections and deduce an intensity value for every section.

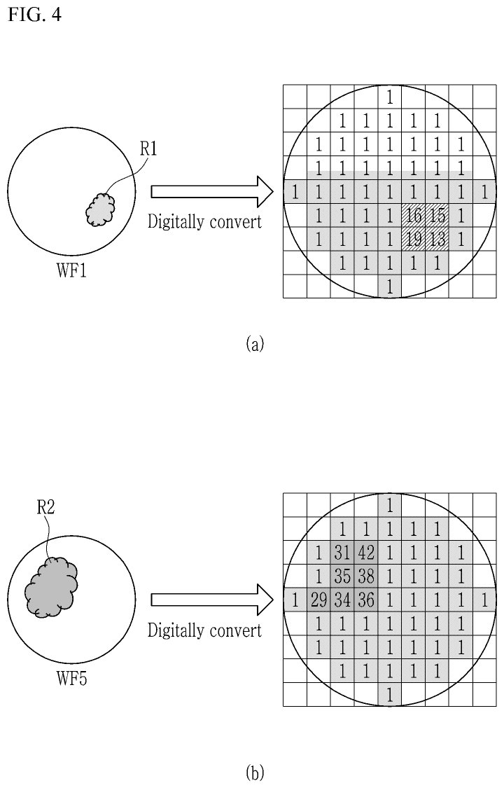

FIG. 4 is a view illustrating an example of converting a macro image of a wafer into digital data.

In FIG. 4(a), the macro image WF1 of the wafer acquired after the CMP process includes a residue image R1 and when the macro image WF1 is converted into the digital data, a conversion value is deduced for each of the plurality of sections. At this time, the value converted into digital data represents an intensity of a luminance corresponding to a film thickness of the wafer and the value may vary depending on the film thickness. For example, in a region in which there is no residue image R1, a value converted into digital data (intensity value) is deduced as “1” and in an region where residue remains, e.g., corresponding to the residue image R1, the film thickness is increased as much as the residue due to the residue so that the converted value (intensity value) is derived as “16”, “15”, “19”, and “13,” e.g., depending on amounts/thicknesses of residues.

In FIG. 4(b), a residue image R2 is included in a macro image WF5 of a wafer acquired after the CMP process. The residue image R2 included in the macro image WF5 shows a dark color (thicker film thickness) image over a region wider than that of the residue image R1 included in the macro image WF1. When the macro image WF5 is converted into digital data, in a region corresponding to the residue image R2, the converted values (intensity values) are deduced as “31”, “42”, “35”, “38”, “29”, “34”, and “36,” e.g., depending on amounts/thicknesses of residues.

As described above, the macro image WF1 and the macro image WF5 of the wafers acquired after the CMP processes represent different levels (size and thickness) of residues.

The residue type determining unit 330 identifies a region (position and size) and a thickness (corresponding to a luminance) of the residue from the digital data converted by the image converter 320 to determine the type of residue. For example, the residue type determining unit 330 identifies a region (position and size) of the residue existing on the wafer through a partition in which the converted digital data value is equal to or higher than a predetermined reference value (for example, 4 or higher) and identifies a film thickness of the residue by inquiring a converted value (intensity value) belonging to the region of the residue from an intensity-thickness matching table (not illustrated).

In an example embodiment, the intensity-thickness matching table may be present in the residue type determining unit 330 and match and store a film thickness value of the residue which is actually measured by a film thickness measurement device (not illustrated) and a converted digital value for the image of the residue (corresponding to the intensity of the luminance).

The additional CMP process condition output unit 340 outputs the customized CMP process condition for every wafer, with respect to wafers which require the additional CMP process, to the operation controller 14, based on the type (residue region and thickness) of the residue determined by the residue type determining unit 330.

By doing this, the operation controller 14 controls an operation of the polishing equipment according to the additional CMP process condition for every wafer received from the additional CMP process condition output unit 340 to perform the additional CMP processes for every wafer customized for wafers which require the additional CMP processes.

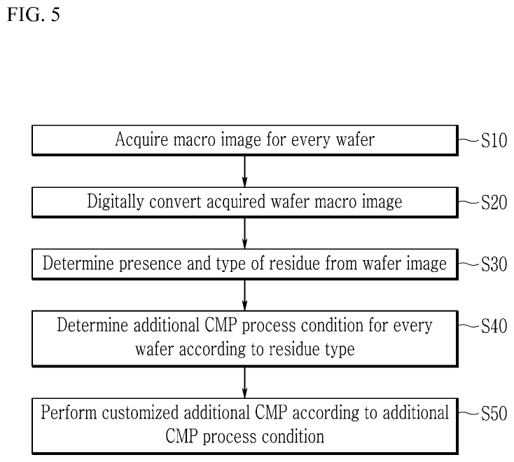

FIG. 5 is a flowchart illustrating a method for performing an additional CMP process according to an example embodiment.

Referring to FIG. 5, the wafer image acquiring unit 310 acquires wafer macro images captured by the camera after CMP processes are performed for every wafer in S10.

The image converter 320 converts the macro image of the wafer into digital data to partition the macro image into a plurality of sections/partitions and deduce an intensity for every section in S20.

The residue type determining unit 330 identifies a region (position and size) and the thickness (corresponding to the luminance) of the residue, from the digital data converted by the image converter 320 to determine the presence and the type of residue.

Next, the additional CMP process condition output unit 340 determines the customized CMP process condition for every wafer, with respect to wafers which require the additional CMP process, based on the type (residue region and thickness) of the residue determined by the residue type determining unit 330.

By doing this, the operation controller 14 controls an operation of the polishing equipment according to the additional CMP process condition for every wafer determined by the additional CMP process condition output unit 340 to perform the additional CMP process for every wafer customized for wafers which require the additional CMP process.

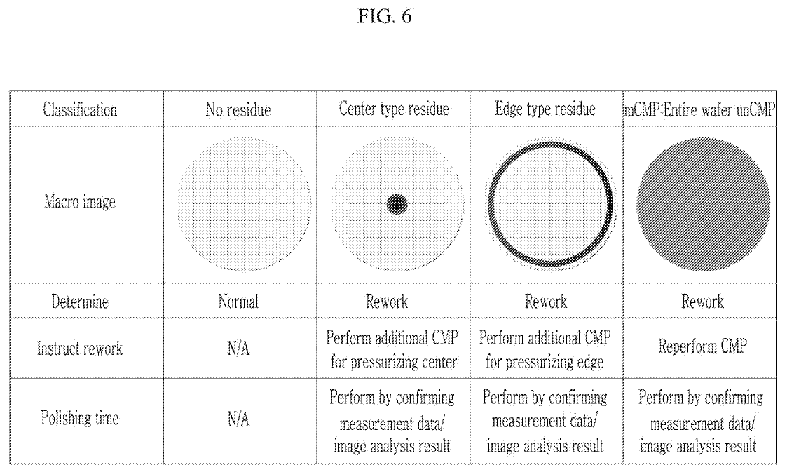

FIG. 6 is a table illustrating residue types and examples of customized additional CMP process conditions according to an example embodiment.

Referring to FIG. 6, when there is no residue in the macro image of the wafer, it is determined to be normal (e.g., pass). When a macro image of the wafer has a residue in the vicinity of the center (center type residue), an additional CMP process condition is determined to perform an additional CMP process for pressurizing a center during a polishing process in which a size and a thickness of the residue are considered. When a macro image of the wafer has a residue in the vicinity of the edge (edge type residue), an additional CMP process condition is determined to perform an additional CMP process for pressurizing an edge during a polishing process in which a size and a thickness of the residue are considered. When the macro image of the wafer entirely has a residue, (entire wafer unCMP), the CMP process is performed again. FIG. 6 illustrates an example of an additional CMP process condition according to an example embodiment, but the present invention is not limited thereto and various types of residues and additional CMP process conditions may be determined.

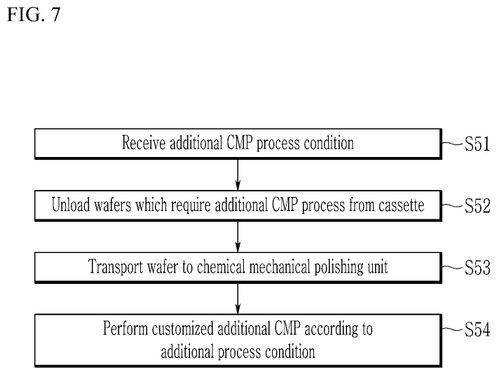

FIG. 7 is a flowchart illustrating a customized additional CMP process according to an example embodiment.

The operation controller 14 receives the additional CMP process condition for every wafer determined by the additional CMP process condition output unit 340 in S51 to transmit a control signal to each polishing equipment according to the additional CMP process condition in S51. At this time, the control signal includes target wafer identification information, target chemical mechanical polishing unit information, and an additional CMP process condition.

The index unit 11 unloads wafers which require the additional CMP process from the cassette in S52. For example, the index unit 11 unloads only a wafer which requires the additional CMP process from the cassette CS according to a control signal from the operation controller 14 to transport the wafer to the transport robot 112.

For example, the unloaded wafer is transported to the chemical mechanical polishing unit in S53. At this time, in the example embodiment, an additional CMP process with different CMP process conditions may be set to be performed for each of the plurality of chemical mechanical polishing units 100.

For example, in accordance with the control signal of the operation controller 14, the exchanger 117 transports the wafer WF transported from the index unit 11 by the transport robot 112 to the load cup 115. Thereafter, the polishing head 142 moves to the polishing platen 120 of the chemical mechanical polishing unit 100 in response to the rotation of the upper base 144 after loading the wafer WF in the load cup 115.

The chemical mechanical polishing unit 100 performs the customized additional CMP process for every wafer according to the control signal of the operation controller 14 in S54. For example, the chemical mechanical polishing unit 100 controls one or more of a slurry amount, a pressure, a polishing time, and a rotation speed by a control signal of the operation controller to perform a customized additional CMP process on the corresponding wafer.

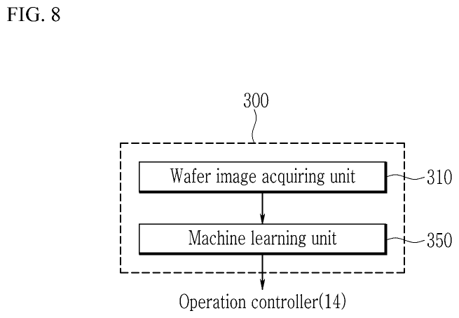

FIG. 8 is a block diagram illustrating an additional CMP process condition generator 300 according to another example embodiment.

An additional CMP process condition generator 300 according to another example embodiment includes a wafer image acquiring unit 310 and a machine learning unit 350.

The wafer image acquiring unit 310 acquires a wafer macro image after the CMP is performed and the wafer macro image is captured by the camera.

The machine learning unit 350 performs the machine learning based on a macro image for a wafer after the CMP, digitally converted data from the macro image, an optimal additional CMP process condition for each macro image to construct a machine learning model. The machine learning unit 350 applies the macro image for/of the wafer after the CMP process is performed on the wafer to the constructed machine learning model to generate a customized CMP process condition for every wafer, with respect to the wafers which require the additional CMP process.

By doing this, the operation controller 14 controls the operation of the polishing equipment according to the additional CMP process condition for every wafer generated by the machine learning unit 350 to perform the additional CMP process for every wafer customized for the wafers which require the additional CMP process.

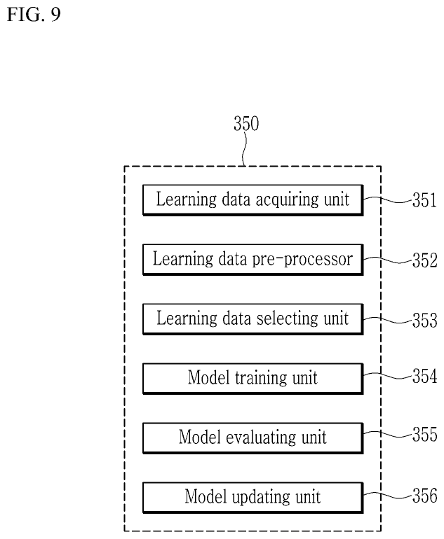

FIG. 9 is a block diagram illustrating a machine learning unit 350 according to an example embodiment.

Referring to FIG. 9, the machine learning unit 350 includes learning data acquiring unit 351, a learning data pre-processor 352, a learning data selecting unit 353, a model training unit 354, a model evaluating unit 355, and a model updating unit 356.

The learning data acquiring unit 351 acquires data required for machine learning. Multiple data may be required for the learning so that the learning data acquiring unit 351 may receive a data set including a plurality of data. Label information may be allocated to each of the plurality of data. The label information may be information explaining the plurality of data. The label information may be information to be deduced by a target task. The label information is input by the user, or acquired from a memory, or acquired from a result of the machine learning model.

For example, the learning data acquiring unit 351 acquires a macro image of the wafer, region and thickness data of the residue extracted from digitally converted data from the macro image, a residue type set based on the region and thickness data of the residue, and the additional CMP process condition of the wafer based on the residue type. At this time, the thickness data of the residue may be acquired by inquiring conversion data (intensity value) belonging to the region of the residue from the intensity-thickness matching table (not illustrated) or acquired from the result of the machine learning model.

The residue type may be labeling information which is directly input by the user based on the region and thickness data of the residue extracted from the digitally converted data from the macro image or acquired from the memory. Further, the optimal additional CMP process condition for the residue type may be acquired input by the user, acquired from the memory, or acquired from the result of the machine learning model.

The learning data pre-processor 352 preprocesses the acquired data to be used for the machine learning. The learning data pre-processor 352 may process the acquired data set in a predetermined format to be used by the model training unit 354 to be described below. For example, the learning data pre-processor 352 may remove a noise or process the macro image acquired by the learning data acquiring unit 351 in a predetermined form to select meaningful data.

The learning data selecting unit 353 selects data required for the learning to determine which region in the image corresponds to information of interest, from the preprocessed data, in accordance with a predetermined determination reference to determine which region of the macro image corresponds to information of interest (residue information). Further, the learning data selecting unit 353 may select the data according to the selected reference set by the learning by the model training unit 354 to be described below.

The learning data selecting unit 353 may have a selected reference for selecting data for every semiconductor process or image data type and select data required for the learning using the selected reference.

The model training unit 354 performs the machine learning using the dataset and label information about the dataset as learning data. Further, the model training unit 354 performs the machine learning further using a previously acquired machine learning model. In this case, the previously acquired machine learning model may be a model which has been constructed in advance. For example, the machine learning model may be a model which receives basic learning data to be constructed in advance.

The machine learning model, for example, may be a neural network based model. For example, a model such as a deep neural network (DNN) or a convolutional neural network (CNN) may be used as a machine learning model, but the machine learning model is not limited thereto.

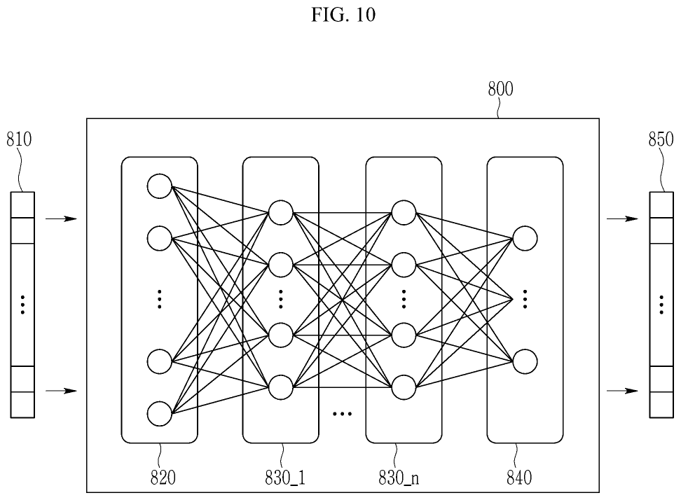

FIG. 10 is an example view illustrating a neural network model 800 according to an example embodiment. A neural network model 800 is an example of the machine learning model and is a statistical learning algorithm implemented based on a structure of a biological neural network or a structure executing the algorithm in a machine learning technique and the cognitive science.

According to an example embodiment, the neural network model 800 may be a machine learning model which has a problem solving ability by allowing nodes which are artificial neurons which form a network by combining synapses, as in the biological neural network, to repeatedly adjust a weight value of the synapses to learn to reduce an error between a correct output corresponding to a specific input and an inferred output. For example, the neural network model 800 includes an arbitrary probability model or a neural network model used for an artificial intelligence learning method, such as machine learning or deep learning.

The neural network model 800 is implemented by a multilayer perceptron (MLP) configured by a plurality of layers of nodes and connection therebetween. The artificial neural network model 800 according to an example embodiment may be implemented using one of various artificial neural network model structures including the MLP. As illustrated in FIG. 10, the artificial neural network model 800 is configured by an input layer 820 which receives an input signal or data 810 from the outside, an output layer 840 which outputs an output signal or data 850 corresponding to input data, and n (n is a positive integer) hidden layers 830_1 to 830_n which is located between the input layer 820 and the output layer 840 and receives the signal from the input layer 820 to extract a characteristic and transmit the characteristic to the output layer 840. Here, the output layer 840 receives the signal from the hidden layers 830_1 to 830_n to output the signal to the outside.

For example, the model training unit 354 learns the machine learning model through the supervised learning with the learning data as an input value.

According to the example embodiment, the model training unit 354 inputs the macro image of the wafer and the residue type to the machine learning model by utilizing the residue type labeled based on the macro image of the wafer and the region and thickness data of the residue extracted from the digitally converted data from the macro image as a training data set to predict (output) an additional CMP process condition corresponding to the residue type. Next, the predicted additional CMP process condition is transmitted to the operation controller 14 to control the operation of the polishing equipment according to the additional CMP process condition for a wafer having the residue type to perform the additional CMP process on the wafer. Next, a feedback of the result (whether there is a residue/whether to be excessively polished/whether to be appropriately polished) of the additional CMP process performed according to the predicted additional CMP process condition is received to update the parameter of the machine learning model.

The model training unit 354, for example, may train the machine learning model by means of the reinforcement learning which uses the feedback indicating whether the result of the target task according to the learning is correct.

When the machine learning model is trained, the model training unit 354 may store the trained machine learning model. In this case, the model training unit 354 may store the trained machine learning model in a memory of an electronic device. Alternatively, the model training unit 354 may store the trained machine learning model in a memory of a server connected to the electronic device via a wired or wireless network.

The model evaluating unit 355 inputs evaluation data to the machine learning model and when a result output from the evaluation data does not satisfy a predetermined reference, causes the model training unit 354 to train the model again. In this case, the evaluation data may be a predetermined data to evaluate the machine learning model.

The model updating unit 356 updates the machine learning model based on the evaluation about the result data obtained by applying selected data to the machine learning model. For example, the model updating unit 356 provides an evaluation result to the model training unit 354 to allow the model training unit 354 to update the machine learning model.

At least one of the learning data acquiring unit 351, the learning data pre-processor 352, the learning data selecting unit 353, the model training unit 354, the model evaluating unit 355, and the model updating unit 356 of the machine learning unit 350 is manufactured as at least one hardware chip to be mounted in the chemical mechanical polishing apparatus 10. For example, at least one of the learning data acquiring unit 351, the learning data pre-processor 352, the learning data selecting unit 353, the model training unit 354, the model evaluating unit 355, and the model updating unit 356 may be manufactured as an exclusive hardware chip for artificial intelligence (AI) or may be manufactured as a part of the general purpose process (for example, a CPU or an application processor) or a graphic use only processor (for example, GPU) to be mounted in the above described chemical mechanical polishing apparatus 10.

Further, some of the learning data acquiring unit 351, the learning data pre-processor 352, the learning data selecting unit 353, the model training unit 354, the model evaluating unit 355, and the model updating unit 356 may be mounted in the chemical mechanical polishing apparatus 10 and the others may be included in a server.

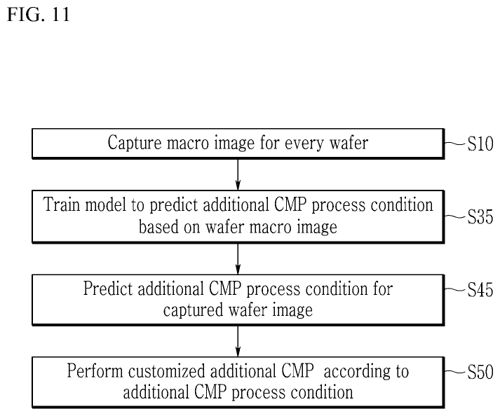

FIG. 11 is a flowchart illustrating a method for performing an additional CMP process according to another example embodiment.

Referring to FIG. 11, the wafer image acquiring unit 310 acquires the wafer macro image after a CMP process is performed, and the wafer macro image is captured by the camera for every wafer in S10.

The machine learning unit 350 performs the machine learning based on the macro image for/of the wafer after CMP process is performed on the wafer, digitally converted value from the macro image, and the optimal additional CMP process condition for each macro image to construct the machine learning model in S35.

Next, the machine learning unit 350 applies the macro image for the wafer after CMP to the constructed learning model to predict the customized CMP process condition for every wafer with respect to wafers which require the additional CMP process in S45.

By doing this, the operation controller 14 controls the operation of the polishing equipment in accordance with the additional CMP process condition for every wafer predicted by the machine learning unit 350 to perform the additional CMP process for every wafer customized for the wafers which require the additional CMP process in S50. At this time, the customized additional CMP process is the same as or similar to the description with reference to FIG. 7, so that the redundant description will be omitted below.

Next, the machine learning unit 350 receives a feedback of the result of the additional CMP process performed according to the predicted additional CMP process condition to update a parameter of the machine learning model.

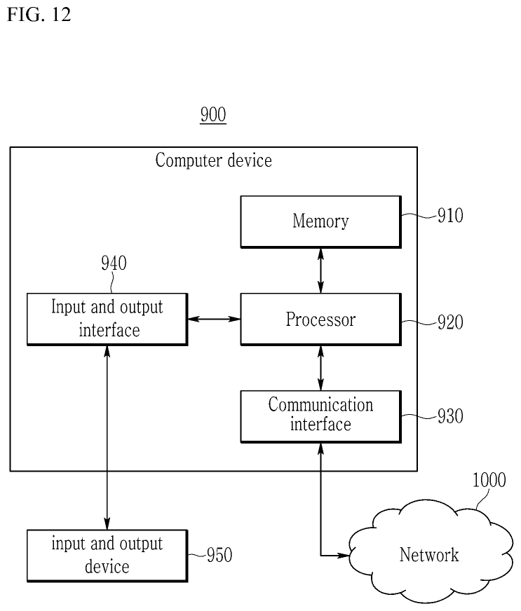

FIG. 12 is a block diagram illustrating an example of a computer device according to an example embodiment. The operation controller 14 or the additional CMP process condition generator 300 which has been described with reference to FIG. 1 may be implemented by a computer device 900 illustrated in FIG. 12.

As illustrated in FIG. 12, the computer device 900 includes a memory 910, a processor 920, a communication interface 930, and an input and output interface 940. The memory 910 is a computer readable recording medium and may include or may be a permanent mass storage device such as a random access memory (RAM), a read only memory (ROM), and a disk drive. Further, an operating system and at least one program code may be stored in the memory 910. The software constituent elements may be loaded from a computer readable recording medium which is separated from the memory 910 onto the memory 910. Such a separate computer readable recording medium may include or may be a computer readable recording medium such as a hard disk, a flash memory, an optical disk, and an external hard disk. Further, the software constituent elements may be loaded in the memory 910 via the communication interface 930.

The processor 920 may be configured to execute the instruction of the computer program by performing a basic arithmetic, logic, and input/output operations. An instruction may be provided to the processor 920 by the memory 910 or the communication interface 930.

The communication interface 930 may provide a function to allow the computer device 900 to communicate with the other devices via a network 1000.

The input and output interface 940 may be a means for interfacing with the input and output device 950. For example, the input device may include or may be a microphone, a keyboard, or a mouse and the output device may include or may be a display or a speaker.

According to the above-described example embodiments, an engineer does not need to manually check the wafer image one by one, but a wafer from which the residue is generated is automatically determined to perform the additional CMP, thereby increasing the productivity. Further, even though the states of the residues of the wafers which require the additional CMP are different from each other, the customized additional CMP for each/every wafer is performed to minimize an excessive CMP.

The above-described embodiments may be implemented in the form of a computer program which can be executed by various components on a computer and the computer program may be recorded in a computer readable media. At this time, examples of the computer readable medium may include a hardware device specifically configured to store and execute program commands, such as magnetic media such as a hard disk drives (HDD), floppy disks and a magnetic tape, optical media such as CD-ROMs and DVDs, magneto-optical media such as floptical disks, or hardware devices such as ROMs, RAMs, and flash memories.

The steps may be performed in an appropriate order unless otherwise specifically identified as an order of performance of steps, which configure the method according to the present example embodiments. However, the present invention is not necessarily limited to the described order of the steps. All the examples and example terms used in the present disclosure are used to describe embodiments of the present invention in detail, but the scope of the present invention is not limited thereby. Further, those skilled in the art may appreciate that various modifications, combinations, and changes may be made within the claims or the equivalents thereof.

Even though different figures illustrate variations of exemplary embodiments and different embodiments disclose different features from each other, these figures and embodiments are not necessarily intended to be mutually exclusive from each other. Rather, features depicted in different figures and/or described above in different embodiments can be combined with other features from other figures/embodiments to result in additional variations of embodiments, when taking the figures and related descriptions of embodiments as a whole into consideration. For example, components and/or features of different embodiments described above can be combined with components and/or features of other embodiments interchangeably or additionally to form additional embodiments unless the context indicates otherwise.

While aspects of the invention have been described in connection with what is presently considered to be practical example embodiments, it is to be understood that the invention is not limited to the disclosed embodiments. On the contrary, it is intended to cover various modifications and equivalent arrangements included within the spirit and scope of the appended claims.

What is claimed is:

1. A chemical mechanical polishing apparatus, comprising:
a polishing platen;
a polishing pad which is located on the polishing platen and includes a polishing surface;
a slurry supplier configured to supply a slurry to the polishing pad;
a polishing head which is located above the polishing pad and configured to mount a wafer thereon; and
an additional CMP process condition generator configured to generate an additional chemical mechanical polishing (CMP) process condition according to a type of residue when there is a residue on a wafer after a CMP process is performed on the wafer.

2. The chemical mechanical polishing apparatus of claim 1, wherein the additional CMP process condition generator includes:
a wafer image acquiring unit configured to acquire a wafer macro image captured by a camera after the CMP process is performed on the wafer;
an image converter configured to convert the wafer macro image acquired by the wafer image acquiring unit into digital data to deduce an intensity value for each of a plurality of partitions of the wafer macro image;
a residue type determining unit configured to determine a type of residue based on the digital data converted by the image converter; and
an additional CMP process condition output unit configured to determine a wafer which requires an additional CMP process based on the type of residue determined by the residue type determining unit and output the additional CMP process condition corresponding to the determined wafer.

3. The chemical mechanical polishing apparatus of claim 2, wherein the type of residue is determined based on a region of the residue and a thickness of the residue.

4. The chemical mechanical polishing apparatus of claim 3, wherein the additional CMP process condition output unit further includes an intensity-thickness matching table in which the intensity value deduced by the image converter and the thickness of the residue match and are stored.

5. The chemical mechanical polishing apparatus of claim 1, wherein the additional CMP process condition generator includes:
a wafer image acquiring unit configured to acquire a wafer macro image captured by a camera after the CMP process is performed on the wafer; and
a machine learning unit configured to construct a machine learning model by performing the machine learning based on the wafer macro image acquired by the wafer image acquiring unit, digitally converted data from the wafer macro image, and an optimal additional CMP process condition corresponding to each macro image.

6. The chemical mechanical polishing apparatus of claim 5, wherein the machine learning unit applies the macro image of the wafer after the CMP process to the constructed machine learning model to determine a wafer which requires the additional CMP process and generate the additional CMP process condition corresponding to the determined wafer.

7. The chemical mechanical polishing apparatus of claim 6, wherein the machine learning unit includes:
a learning data acquiring unit configured to acquire a wafer macro image captured by the camera after the CMP process is performed, a residue type extracted from the digitally converted data from the wafer macro image, and an additional CMP process condition of the wafer based on the residue type; and
a model training unit configured to input the wafer macro image and the residue type to the machine learning model to predict an additional CMP process condition corresponding to the residue type.

8. The chemical mechanical polishing apparatus of claim 7, wherein the residue type is labeling information which is acquired from a memory or directly input by a user based on a region of the residue extracted from the digitally converted data and thickness data of the residue.

9. The chemical mechanical polishing apparatus of claim 7, wherein the machine learning unit further includes:
a learning data pre-processor configured to preprocess the acquired data to allow the learning data acquiring unit to use the acquired data for the machine learning; and
a learning data selecting unit configured to select data required for learning, among the preprocessed data, according to a predetermined reference to determine which region of the wafer macro image corresponds to information of interest.

10. The chemical mechanical polishing apparatus of claim 7, wherein the model training unit inputs the wafer macro image and the residue type to a machine learning model to predict an additional CMP process condition corresponding to the residue type and receives a feedback of a result of the additional CMP process performed according to the predicted additional CMP process condition to update a parameter of the machine learning model.

11. Chemical mechanical polishing equipment comprising:
a chemical mechanical polishing apparatus which includes at least one chemical mechanical polishing unit which individually performs a chemical mechanical polishing (CMP) process on a wafer;
an index unit configured to provide a space in which a cassette which accommodates a plurality of wafers is placed;
a transport robot configured to transport the wafer between the chemical mechanical polishing apparatus and the index unit;
a cleaning apparatus configured to remove a contaminated material remaining on a wafer after the CMP process is performed on the wafer; and
an operation controller configured to generate a control signal according to an additional CMP process condition according to a type of residue when there is a residue on a wafer after the CMP process is performed on the wafer and to transmit the control signal to the chemical mechanical polishing apparatus.

12. The chemical mechanical polishing equipment of claim 11, wherein the chemical mechanical polishing unit includes:
a polishing platen;
a polishing pad which is located on the polishing platen and includes a polishing surface;
a slurry supplier configured to supply a slurry to the polishing pad;
a polishing head which is located above the polishing pad and configured to mount a wafer thereon; and
an additional CMP process condition generator configured to generate an additional chemical mechanical polishing (CMP) process condition according to a type of residue to output the additional CMP process condition to the operation controller when there is a residue on a wafer after the CMP process is performed on the wafer.

13. The chemical mechanical polishing equipment of claim 12, wherein the operation controller transmits a control signal corresponding to individual CMP process conditions to the chemical mechanical polishing unit.

14. The chemical mechanical polishing equipment of claim 12, wherein the additional CMP process condition generator includes:
a wafer image acquiring unit configured to acquire a wafer macro image captured by a camera after the CMP process is performed on the wafer;
an image converter configured to convert the wafer macro image into digital data to deduce an intensity value for each of a plurality of partitions of the wafer macro image;
a residue type determining unit configured to determine a type of residue based on the digital data converted by the image converter; and
an addition CMP process condition output unit configured to determine a wafer which requires an additional CMP process based on the type of residue determined by the residue type determining unit and output the additional CMP process condition corresponding to the determined wafer.

15. The chemical mechanical polishing equipment of claim 12, wherein the additional CMP process condition generator includes:
a wafer image acquiring unit configured to acquire a wafer macro image captured by a camera after the CMP process is performed on the wafer; and
a machine learning unit configured to construct a machine learning model by performing the machine learning based on the wafer macro image acquired by the wafer image acquiring unit, digitally converted data from the wafer macro image, and an optimal additional CMP process condition corresponding to each macro image.

16. The chemical mechanical polishing equipment of claim 15, wherein the machine learning unit includes
a learning data acquiring unit configured to acquire a wafer macro image captured by the camera after the CMP process is performed on the wafer, a residue type extracted from the digitally converted data from the wafer macro image, and an additional CMP process condition of the wafer based on the residue type; and
a model training unit configured to input the wafer macro image and the residue type to the machine learning model to predict an additional CMP process condition corresponding to the residue type.

17. The chemical mechanical polishing equipment of claim 16, wherein the model training unit inputs the wafer macro image and the residue type to a machine learning model to predict an additional CMP process condition corresponding to the residue type and receives a feedback of a result of the additional CMP process performed according to the predicted additional CMP process condition to update a parameter of the machine learning model.

18. A chemical mechanical polishing method which is a chemical mechanical polishing method performed by a chemical mechanical polishing apparatus including at least one chemical mechanical polishing unit configured to individually perform a chemical mechanical polishing (CMP) process on a wafer, the method comprising:
acquiring a wafer macro image after the CMP process is performed on a wafer;
determining an additional CMP process condition corresponding to a wafer which requires an additional CMP process, based on a type of a residue determined from the wafer macro image;
transmitting a control signal corresponding to the determined additional CMP process condition to the chemical mechanical polishing unit; and
performing the additional CMP process on the wafer by the chemical mechanical polishing unit based on the transmitted control signal.

19. The chemical mechanical polishing method of claim 18, wherein the determining of an additional CMP process condition includes:
constructing a machine learning model by performing the machine learning based on the wafer macro image after the CMP process, digitally converted data from the wafer macro image, and an optimal additional CMP process condition corresponding to each macro image; and
predicting a customized additional CMP process condition with respect to a wafer which requires the additional CMP process by applying the macro image of the wafer to the constructed machine learning model.

20. The chemical mechanical polishing method of claim 19, wherein the determining of an additional CMP process condition further includes:
updating a parameter of the machine learning model by receiving a feedback of a result of the additional CMP process performed according to the predicted additional CMP process condition.
